(19) United States
(12) Patent Application Publication
(10) Pub. No.: US 2026/0039315 A1
(43) Pub. Date: Feb. 5, 2026

(54) ERROR PROCESSING

(71) Applicant: Infineon Technologies AG, Neubiberg (DE)

(72) Inventors: Thomas Kern, Aschheim (DE); Alexander Klockmann, Taufkirchen (DE); Michael Goessel, Mahlow (DE)

(21) Appl. No.: 19/277,636

(22) Filed: Jul. 23, 2025

(30) Foreign Application Priority Data
Jul. 30, 2024 (DE) 10 2024 207 164.1

(51) Int. Cl. H03M 13/15

(52) U.S. Cl. CPC H03M 13/1575; H03M 13/152

(57) ABSTRACT

The approaches proposed here relate to error processing by means of at least two error processing branches. Each of the error processing branches is configured (i) to process a data word, wherein the data words of the error processing branches differ in at least one bit, and (ii) to provide a processed data word to a decision unit. The decision unit is configured to select one of the processed data words or to perform a predetermined action if an uncorrectable error has been detected.

### REFERENCE TO RELATED APPLICATION

This Application claims priority to German Application number 10 2024 207 164.1, filed on Jul. 30, 2024, the contents of which are hereby incorporated by reference in their entirety.

### BACKGROUND

The approaches presented here relate to error processing, in particular error detection, optionally as a preliminary stage to a subsequent error correction.

In particular, the object of the invention is to improve existing approaches and raise the performance level of error detection.

This object is achieved in accordance with the features of the independent claims. Preferred embodiments can be gathered from the dependent claims, in particular.

These examples proposed herein may be based on at least one of the following solutions. In particular, combinations of the following features can be used to achieve a desired result. The features of the device may be combined with features of the method or vice versa.

### SUMMARY

To achieve the object, a device for error processing is proposed,
including at least two error processing branches, each error processing branch including:
   a syndrome generator,
   an error detection unit and
   an error correction unit,
wherein each of the error processing branches is configured
   to process a data word, wherein the data words of the error processing branches differ in at least one bit and
   to provide a processed data word,
a decision unit configured to select one of the processed data words or to perform a predetermined action if an uncorrectable error has been detected.

In a further development, the at least two error processing branches are at least partially operable simultaneously.

In a further development, each of the error processing branches is configured to process the data word by
using the syndrome generator to determine at least one syndrome,
using the error detection to determine, based on the at least one syndrome, whether at least one error is present,
if at least one error is present, triggering a correction of the at least one error by means of the error correction unit and providing a corrected data word or other information to the decision unit or,
if no error could be determined, providing the data word to the decision unit.

In a further development, on the basis of the other information it can be determined that an uncorrectable error is present.

In a further development, the data words of the error processing branches differ in at least one bit, the at least one bit being determined on the basis of an uncertainty interval between two reference values.

In a further development, the device additionally includes a memory reading component which is configured to determine the data words of the error processing branches by means of two reference values, the two reference values defining an uncertainty interval.

In a further development, the data words of the error processing branches differ in at least one further bit, the at least one further bit being an incorrect bit which is not in the uncertainty interval.

In a further development, the error correction unit is configured to perform a correction based on an error code, the error code being one of the following:
a t-bit error correcting code with QI,
a t-bit error correcting BCH code or a t-bit error correcting BCH code with included parity over a Galois field GF(2^{q}), which has t syndrome components from the Galois field GF(2^{q}) and with t>2 and q>3,
a Hamming code,
a Hsiao code,
a shortened Hamming code,
a BCH code,
a shortened BCH code or
a Reed-Muller code.

In a further development, the processed data word is an uncorrected or a corrected data word.

In a further development, the decision unit is configured to perform the selection of one of the data words based on a prioritization.

In a further development, the prioritization prefers the corrected or uncorrected data word of the error processing branch which had the fewest errors prior to the correction.

In a further development, the decision unit is configured to select one of the data words based on a comparison of the processed data words of the error processing branches with the original data words provided to the error processing branches.

Furthermore, a method for error processing is proposed
having at least two error processing branches, each error processing branch including a syndrome generator, an error detection unit and an error correction unit,
wherein each of the error processing branches performs the following steps:
   processing a data word, wherein the data words of the error processing branches differ in at least one bit and
   providing a processed data word,
wherein a decision unit selects one of the processed data words or performs a predetermined action if an uncorrectable error has been detected.

In a further development, each of the error processing branches performs the following steps:
determining at least one syndrome by means of the syndrome generator,
using the error detection to determine, on the basis of the at least one syndrome, whether at least one error is present,
if at least one error is present, using the error correction unit to trigger a correction of the at least one error and providing a corrected data word or other information for the decision unit, or
if no error could be determined, providing the data word for the decision unit.

In a further development, on the basis of the other information it can be determined that an uncorrectable error is present.

In a further development, the data words of the error processing branches differ in at least one bit, the at least one bit being determined on the basis of an uncertainty interval between two reference values.

In a further development, the data words of the error processing branches differ in at least one further bit, the at least one further bit being an incorrect bit which is not in the uncertainty interval.

### BRIEF DESCRIPTION OF THE DRAWINGS

The above-described properties, features and advantages of this invention and the way in which they are achieved will be explained further in association with a schematic description of exemplary embodiments which are explained in greater detail in association with the drawings. In this case, identical or identically acting elements may be provided with identical reference signs, for the sake of clarity.

FIG. 1 shows two overlapping distributions of physical values for memory cells of a memory with two reference values and an overlap region as an uncertainty range, in accordance with various aspects described.

FIG. 2 shows an example diagram including two separate branches for error processing, which can be executed at least partially in parallel to each other, in accordance with various aspects described.

FIG. 3 shows two distributions of physical values that do not overlap, with an uncertainty range defined by two reference values located in a region between the two distributions, in accordance with various aspects described.

FIG. 4 shows a diagram showing two data words before and two data words after the correction, in accordance with various aspects described.

### DETAILED DESCRIPTION

To increase the reliability of data stored in memory cells and read from memory cells, it is an option to use at least two reference values when reading the data. For example, reference is made to DE 10 2020 100 541 A1 in this regard.

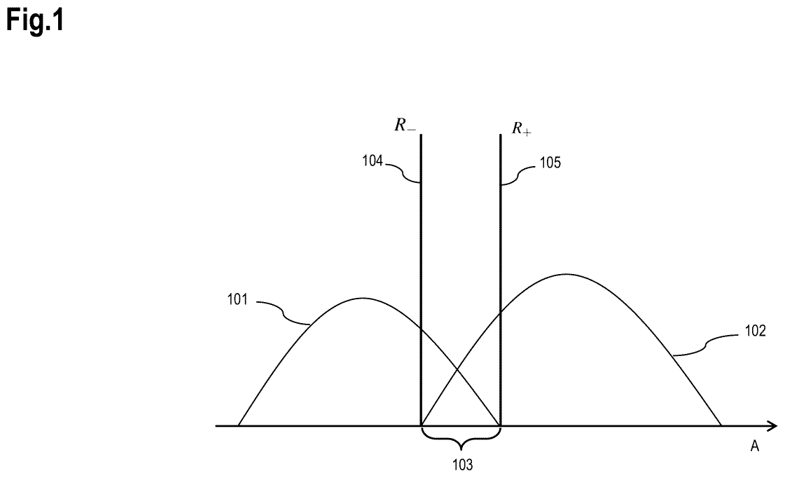

FIG. I shows distributions of physical values A for memory cells of a memory. The physical value A is, for example, a cell current through the memory cell or a voltage that is dropped across the memory cell. Distribution 101 is assigned to a binary value 1 and distribution 102 is assigned to a binary value 0. An uncertainty range 103 corresponds to an overlap region of the distributions 101 and 102 in FIG. 1.

Furthermore, a reference value R₊ 105 and a reference value R₋ 104 are shown, where R₊−R₋>0.

The value A is assigned the binary value 0 if A≤R⁻. Accordingly, the value A is assigned the binary value 1 if A>R⁺.

If R⁻<A<R⁺, the value A is in the overlap region 103, hence the value A can correspond to either the binary value 0 or the binary value 1. Two data words can be determined and further processed for the value A. This is described, for example, in DE 10 2020 100 541 A1.

If the value A is in the overlap region 103, there are two possible data words W0 and W1. The data word W0 is assigned the binary value x and the data word W1 is assigned the inverted binary value x for the bit position in question. Thus, the data words W0 and W1 differ in a single unreliable bit. One of the data words W0 or W1 is the correct data word, the other is incorrect.

Each data word can be (possibly also with additional bits) a code word of an error code in the error-free case. The term error code as used here denotes a code that can detect errors or a code that can both detect and correct errors.

For example, an error code can be used that can correct t-bit errors, or an error code can be used that can correct t-bit errors and detect (t+1)-bit errors.

Examples of possible error codes are:
a Hamming code correcting 1-bit errors,
a Hsiao code correcting 1-bit errors and detecting 2-bit errors,
a t-bit error-correcting BCH code,
a BCH code correcting t-bit errors and detecting (t+1)-bit errors with t>2,
a shortened code, such as a shortened Hamming code.

If a word of a certain word width (predefined, for example, by a number of bits that is determined by an address bus) is read from a memory, this word may also have multiple unreliable bits. Any unreliable bit can have the value 0 or the value 1.

For example, it is proposed to provide error processing that efficiently allows the determination of the correct codeword based on multiple data words resulting from the read operation.

For example, at least two reference values can be used when reading out the data.

It is also advantageous that the data to be stored is transformed into code words in such a way that a readout can be carried out in a time domain. For details regarding the readout of memory cells in the time domain, reference is made to U.S. Pat. No. 9,805,771 B2: in this case, a read current, which is formed during readout as a function of a resistance value stored in the memory cell, is integrated in a capacitor. The value 1 can be assigned to each of the memory cells which in chronological order are the fastest to reach a specified voltage of the capacitor, and the cells which are the slowest cells to reach the specified voltage can each be assigned the value 0. An example 4-from-8 code will serve to illustrate the principle: when reading out from the memory in the time domain, the read operation can advantageously be terminated as soon as 4 bits of the same type, i.e. either the value 0 four times or the value 1 four times, have been read. The respective other value is then assumed for the remaining bits that have not yet arrived. This approach takes advantage of the property of the 4-from-8 code, in which codewords always have 4 ones and 4 zeros.

The approach presented here enables in particular an accelerated error correction to be performed and increases the security in the detection of multiple-bit errors (also referred to as multi-bit errors).

In particular, errors can be detected in the syndrome determination, e.g. in syndrome generators, and/or in downstream error correction units.

One option is that the respective data word is not corrected (or is further processed without correction) provided there is no error present or no error could be detected. It should be noted that the data word may nevertheless be incorrect if, for example, there is an undetectable or uncorrectable error present.

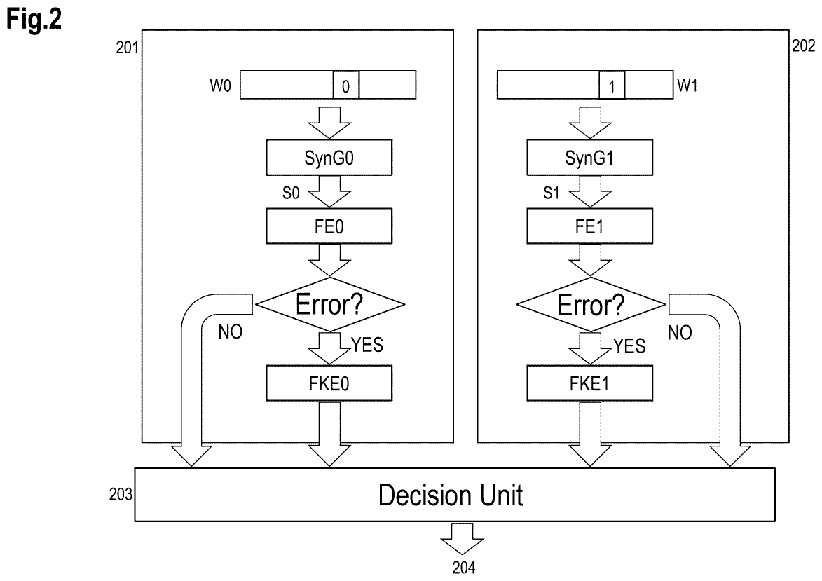

FIG. 2 shows an example diagram including two separate branches 201 and 202, which can be executed at least partially overlapping in time (i.e. at least partially in parallel) with each other.

First, as described above, a data word is read from a memory. The data word contains, for example, a single unreliable bit. In a data word W0 the unreliable bit is set to the value 0 and in a data word W1 the unreliable bit is set to the value 1.

The data word W0 is processed in branch 201: For this purpose, an error syndrome S0 is determined by means of a syndrome generator SynG0. Based on the error syndrome S0, an error detection unit FE0 determines whether an error is detected. If an error is detected, the error is corrected using an error correction unit FKE0. The corrected data word is then fed to a decision unit 203. If no error is detected by the error detection unit FE0, the data word W0 detected as being error-free can be fed to the decision unit 203. The syndrome generator SynG0, the error detection unit FE0 and the error correction unit FKE0 are part of branch 201. The decision as to whether an error could be detected can be, for example, part of the error detection unit FE0, part of the error correction unit FKE0 or implemented separately from these.

The data word W1 is processed in branch 202: For this purpose, an error syndrome S1 is determined by means of a syndrome generator SynG1. Based on the error syndrome S1, an error detection unit FE1 determines whether an error is detected. If an error is detected, the error is corrected using an error correction unit FKE1. The corrected data word is then fed to the decision unit 203. If no error is detected by the error detection unit FE1, the data word W1 detected as being error-free can be fed to the decision unit 203. The syndrome generator SynG1, error detection unit FE1 and error correction unit FKE1 are part of branch 202. The decision as to whether an error could be detected can be, for example, part of the error detection unit FE1, part of the error correction unit FKE1 or implemented separately from these.

FIG. 2 thus shows two parallel branches 201 and 202 with two syndrome generators SynG0, SynG1, two error detection units FEE0, FEE1 and two error correction units FKE0, FKE1.

The decision unit 203 can make a prioritized decision as to which corrected or uncorrected data word to provide at its output 204 for further processing: for example, it can prefer to further process the data word that did not have to be corrected. If both data words were corrected, it could prefer to select the data word that had the lower number of errors before the correction. It is also possible for the decision unit to display or provide information that can be used to determine that there is an uncorrectable error present.

In the above example, an unreliable bit was assumed. It is also possible that the data words W0 and W1 differ in more than one bit. In such a case, the data words W0 and W1 can be combined using an XOR operation (XOR=exclusive OR), the result of the XOR operation on two bits is always equal to 1 if the two bits are different. The number of ones thus corresponds to the number of unreliable bits for the read data word. Using the different branches, the error detection and error correction are independent for different data words and enable the determination of the number of errors per branch and error positions. The results provided by the branches can be compared with each other. This results in possible actions, e.g. the forwarding or further processing of corrected data words or the detection of and response to uncorrectable errors.

### Example: Integrity Checking

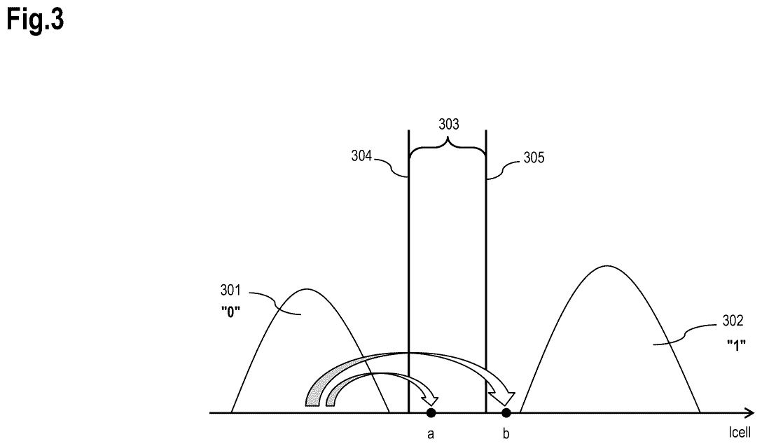

FIG. 3 shows two distributions 301, 302 of physical values (here by way of example: cell currents through a memory cell), wherein the distribution 301 represents a binary value 0 and the distribution 302 represents a binary value 1. The distributions 301 and 302 do not overlap, two reference values 304, 305 are located between the distributions 301, 302, and the range between the reference values 304 and 305 corresponds to an uncertainty range 303.

In the following example, a word having multiple bits is read. The word contains a bit a, which actually has the value 0, but falls within the uncertainty range 303 during reading. The bit a is therefore an unreliable bit according to the above statements.

Furthermore, the word includes a bit b, which is corrupted from the value 0 to the value 1 during reading. Bit b is not in the range of one of distributions 301, 302 and does not fall into the uncertainty range 303.

In accordance with the above statements on unreliable bits that fall into an uncertainty range, subsequently in a word W0 the bit a=0 is set and in a word W1 the bit a=1 is set. The words W0 and W1 can be processed according to FIG. 2 using the branches 201, 202. After the correction, a corrected word W0* results from branch 201 and a corrected word W1* results from branch 202.

The word W0 contains only the incorrect bit b, i.e. a single error, which has been corrected in the word W0*. The word W1 contains the incorrect bit b and also the corrupted bit a, i.e. two errors.

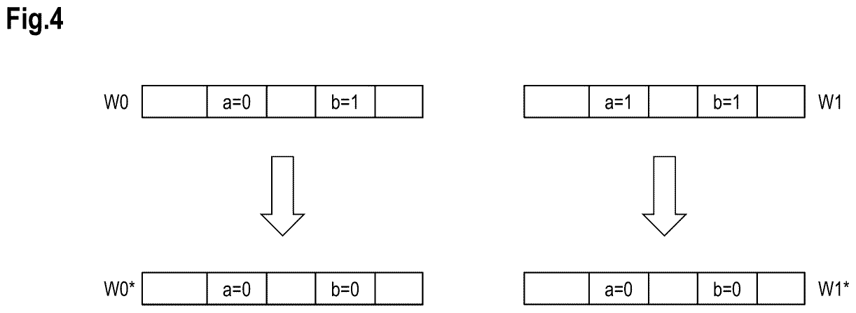

FIG. 4 shows a diagram showing the words W0 and W1 before the correction and the words W0* and W1* after the correction.

After correction, the words W0 and W0* can be compared with each other (using an XOR operation): it is found that an error (the incorrect bit b) has been corrected. The words W1 and W1* can be compared in the same way: in this case there is a difference in the two bits a and b, two errors have been corrected.

This means it is possible to determine whether the maximum number of detectable errors is greater than or equal to the number of unreliable bits.

### Example: Detection of Uncorrectable Multi-Bit Errors

In particular in the case of multi-bit errors, the problem arises that a codeword can be corrupted into a different codeword and thus the multi-bit error remains undetected. The approach proposed here has the advantage that, due to the parallelized processing shown in FIG. 2 by means of the branches 201 and 202, an assignment occurring in branch 201 that leads to a corrupted code word cannot also occur in branch 202 (because a different assignment, i.e. assignment of the bits, is selected for this branch 202). Thus, by means of branch 202, it can be detected, for example, that a multi-bit error is present which cannot be corrected, even if branch 201 returns a corrected but nevertheless incorrect codeword. In this case, the decision unit 203 can be used to determine that there is an uncorrectable error present and the corrected word from branch 201 is a corrupted codeword.

What is claimed is:

1. A device for error processing, comprising at least two error processing branches, each error processing branch comprising:
a syndrome generator,
an error detection unit and
an error correction unit,
wherein each of the error processing branches is configured to process a data word, wherein the data words of the error processing branches differ in at least one bit, and provide a processed data word, and
a decision unit configured to select one of the processed data words or to perform a predetermined action if an uncorrectable error has been detected.

2. The device of claim 1, wherein the at least two error processing branches are at least partially operable simultaneously.

3. The device of claim 1, wherein each of the error processing branches is configured to process the data word by
using the syndrome generator to determine at least one syndrome,
using the error detection to determine, based on the at least one syndrome, whether at least one error is present,
if at least one error is present, triggering a correction of the at least one error by means of the error correction unit and providing a corrected data word or other information to the decision unit or,
if no error could be determined, providing the data word to the decision unit.

4. The device as claimed in claim 3, wherein based on other information it can be determined that an uncorrectable error is present.

5. The device of claim 1, wherein the data words of the error processing branches differ in at least one bit, the at least one bit being determined based on an uncertainty interval between two reference values.

6. The device of claim 1, comprising a memory reading component, which is configured to determine the data words of the error processing branches by means of two reference values, the two reference values defining an uncertainty interval.

7. The device of claim 1, wherein the data words of the error processing branches differ in at least one further bit, the at least one further bit being an incorrect bit which is outside an uncertainty interval between two reference values.

8. The device of claim 1, wherein the error correction unit is configured to perform a correction based on an error code, wherein the error code comprises one of
a t-bit error correcting code with QI,
a t-bit error correcting BCH code or a t-bit error correcting BCH code with included parity over a Galois field GF(2^{q}), which has t syndrome components from the Galois field GF(2^{q}) and with t>2 and q>3,
a Hamming code,
a Hsiao code,
a shortened Hamming code,
a BCH code,
a shortened BCH code, or
a Reed-Muller code.

9. The device of claim 1, wherein the processed data word is an uncorrected or a corrected data word.

10. The device of claim 1, wherein the decision unit is configured to perform the selection of one of the data words based on a prioritization.

11. The device of claim 10, wherein the prioritization prefers the corrected or uncorrected data word of the error processing branch which had the fewest errors prior to the correction.

12. The device of claim 1, wherein the decision unit is configured to select one of the data words based on a comparison of the processed data words of the error processing branches with the original data words provided to the error processing branches.

13. A method, comprising:
with each error processing branch of at least two error processing branches, processing a data word, wherein the data words of the error processing branches differ in at least one bit, and providing a processed data word to a decision unit; and
with the decision unit, selecting one of the processed data words or, if an uncorrectable error has been detected, performing a predetermined action.

14. The method of claim 13, comprising, with each of the error processing branches,
determining at least one syndrome by way of a syndrome generator,
using the error detection to determine, on the basis of the at least one syndrome, whether at least one error is present,
if at least one error is present, using an error correction unit to trigger a correction of the at least one error and providing a corrected data word or other information for the decision unit, or
if no error could be determined, providing the data word for the decision unit.

15. The method of claim 14, comprising determining that an uncorrectable error is present on the basis of the other information.

16. The method of claim 13, wherein the data words of the error processing branches differ in at least one bit, the at least one bit being determined on the basis of an uncertainty interval between two reference values.

17. The method of claim 16, wherein the data words of the error processing branches differ in at least one further bit, the at least one further bit being an incorrect bit which is not in the uncertainty interval.

18. An error correction system, comprising
two error processing branches arranged in parallel and configured to process a data word; and
a decision unit;
wherein each error processing branch is configured to, in response to a value in the data word having a bit value falling within an uncertainty interval,
set the bit value to a predetermined value to generate a resulting data word, the predetermined value for the two error processing branches being different, so that the resulting data word processed by each error processing branch differ by at least one bit;
detecting whether the resulting data word contains an error, and
when the resulting data word does not contain an error provide the resulting data word as a processed data word to the decision unit; or
when the resulting data word contains an error, correcting the resulting data word based on an error code to generate a corrected data word and providing the corrected data word as a processed data word to the decision unit; and
wherein the decision unit is configured to select a processed data word provided by one of the error processing branches to output.

19. The error correction system of claim 18, wherein
each processing branch is further configured to determine a number of corrected bits for a processed data word based on a comparison between the data word and the processed data word, and
the decision unit selects a processed data word based on the number of corrected bits for each processed data word.

20. The error correction system of claim 18, wherein the uncertainty interval corresponds to bit values that fall within a range of bit values assigned to a bit value of 1 and an overlapping range of bit values assigned to a bit value of 0.
